(19) United States
(12) Patent Application Publication
(10) Pub. No.: US 2010/0142293 A1
(43) Pub. Date: Jun. 10, 2010

(54) Boosting voltage generating circuit, negative voltage generating circuit, step-down voltage generating circuit, and semiconductor device

(75) Inventor: Koichiro Hayashi, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/591,879

(22) Filed: Dec. 3, 2009

(30) Foreign Application Priority Data
Dec. 8, 2008 (JP) 2008-312177

(51) Int. Cl. G11C 7/00; G05F 1/10; H02J 3/12

(52) U.S. Cl. 365/191; 327/535; 323/234

(57) ABSTRACT

In a boosting voltage generating circuit, a boosting circuit unit generates boosting voltage according to a value of boosting voltage output by the boosting voltage generating circuit and an auxiliary boosting circuit unit supplies, immediately before electric current is consumed by a load supplied with the boosting voltage, voltage higher than the boosting voltage corresponding to the amount of current consumed by the load, to the load. The auxiliary boosting circuit unit raises the voltage supplied to the load to an optimum amount before the boosting voltage drops.

### BACKGROUND OF THE INVENTION

1. Field of the Invention

The present invention relates to a boosting voltage generating circuit that generates boosting voltage, a negative voltage generating circuit that generates negative voltage, a step-down voltage generating circuit that generates step-down voltage, and a semiconductor device including an internal voltage generating circuit that generates internal voltage.

2. Description of Related Art

In a semiconductor memory device in recent years, reliability of elements is improved by, instead of directly using power supply voltage supplied from the outside, stepping down or boosting the power supply voltage to generate predetermined internal power supply voltage and supplying the generated internal power supply voltage to an internal circuit.

For example, in a DRAM, the transistor size for a memory cell is microminiaturized in order to increase memory capacity. Therefore, since high voltage cannot be applied to a transistor, a step-down power supply circuit is provided in the inside and step-down voltage that is lower than the external power supply voltage is supplied to the transistor.

On the other hand, it is necessary to supply boosting voltage higher than the external power supply voltage to word lines in order to secure the desired performance. Further, a semiconductor substrate may be biased to a negative voltage in order to improve the charge retaining characteristic of the memory cell. In this way, the semiconductor memory device includes the internal voltage generating circuit that generates various internal power supply voltages.

As the boosting voltage generating circuit that generates the boosting voltage, for example, there is the configuration described in Japanese Patent Laid-Open No. 9-153284. The configuration of the boosting voltage generating circuit of the related art is shown in FIG. 1.

As shown in FIG. 1, the boosting voltage generating circuit of the related art includes boosting voltage detecting circuit 10, oscillator 11, incidental pulse generating circuit 12, and boosting circuit unit 30.

Boosting voltage detecting circuit 10 sets a boosting voltage detection signal to a high level to actuate oscillator 11 when the boosting voltage output by the boosting voltage generating circuit is lower than a predetermined voltage value. On the other hand, when the boosting voltage is equal to or higher than the predetermined voltage value, boosting voltage detecting circuit 10 sets the boosting voltage detection signal to a low level to stop oscillator 11. Boosting voltage detecting circuit 10 outputs the boosting voltage detection signal to boosting circuit unit 30 as well. Boosting circuit unit 30 raises the boosting voltage when the boosting voltage detection signal is at the high level or when an oscillation signal is output from oscillator 11 and stops boosting operation when the oscillation signal is not output. In this way, the boosting voltage generating circuit outputs fixed boosting voltage.

In the related art shown in FIG. 1, incidental pulse generating circuit 12 outputs a sub-signal. When the sub-signal is input from incidental pulse generating circuit 12, boosting circuit unit 30 raises the boosting voltage even when the boosting voltage has not dropped.

FIG. 2 is a waveform chart showing the operation of boosting voltage generating circuit shown in FIG. 1.

As shown in FIG. 2, when electric current is consumed by a not-shown load connected to an output of the boosting voltage generating circuit, the boosting voltage output from the boosting voltage generating circuit drops. When boosting voltage detecting circuit 10 detects that the boosting voltage has dropped, boosting voltage detecting circuit 10 sets the boosting voltage detection signal to the high level to actuate oscillator 11 and causes boosting circuit unit 30 to raise the boosting voltage. When boosting voltage detecting circuit 10 detects that the boosting voltage rises higher than the predetermined voltage value, boosting voltage detecting circuit 10 sets the boosting voltage detection signal to the low level to stop oscillator 11 and causes boosting circuit unit 30 to stop the boosting operation. When the boosting operation of boosting circuit unit 30 stops, the rise of the boosting voltage stops.

When the sub-signal output from incidental pulse generating circuit 12 changes to the high level before electric current is consumed by the load, boosting circuit unit 30 raises the boosting voltage. By raising the boosting voltage in advance, it is possible to reduce time until the dropped boosting voltage returns to the predetermined voltage value.

In the internal voltage generating circuit such as the boosting voltage generating circuit of the related art explained above, fluctuation in the internal voltage is large because the internal voltage is raised or lowered more than necessary until it is detected that the internal voltage reaches the predetermined voltage value.

### SUMMARY

In a boosting voltage generating circuit, a boosting circuit unit generates boosting voltage according to a value of the boosting voltage output by the boosting voltage generating circuit and an auxiliary boosting circuit unit supplies, immediately before electric current is consumed by a load supplied with the boosting voltage, voltage higher than the boosting voltage that corresponds to the current amount consumed by the load, to the load.

The auxiliary boosting circuit unit raises the voltage supplied to the load to an optimum amount before the boosting voltage drops. Therefore, the auxiliary boosting circuit unit can suppress the drop in the boosting voltage at the time when electric current is consumed by the load.

The boosting circuit unit boosts the dropped boosting voltage in order to reset the boosting voltage to a predetermined voltage value only when a slight drop in the boosting voltage, at the time when electric current is consumed by the load, or when voltage drop due to very small current consumption not notified by a boosting control signal is detected. Therefore, since the amounts of boosting voltage of the boosting circuit unit can be designed small, it is possible to prevent the boosting voltage from rising more than necessary.

In a negative voltage generating circuit, a negative voltage circuit unit generates negative voltage according to the value of negative voltage output by the negative voltage generating circuit and an auxiliary negative voltage circuit unit supplies, immediately before electric current is consumed by a load supplied with the negative voltage, voltage that is lower than the negative voltage that corresponds to the current amount consumed by the load, to the load.

The auxiliary negative voltage circuit unit lowers the voltage supplied to the load to an optimum amount before the negative voltage rises. Therefore, the auxiliary negative voltage circuit unit can suppress the rise of the negative voltage at the time when electric current is consumed by the load.

The negative voltage circuit unit supplies the negative voltage in order to reset the raised negative voltage to a predetermined voltage value only when a slight rise in the negative voltage, at the time when electric current is consumed by the load, or when voltage rise due to very small current consumption not notified by a negative voltage control signal is detected. Therefore, since the amounts of voltage drop of the negative voltage circuit unit can be designed small, it is possible to prevent the negative voltage from dropping more than necessary.

In a step-down voltage generating circuit, a differential amplifier brings step-down voltage output by the step-down voltage generating circuit close to a predetermined voltage value and an auxiliary step-down voltage circuit unit supplies, immediately before electric current is consumed by a load supplied with the step-down voltage, voltage that corresponds to the current amount consumed by the load, to the load.

The auxiliary step-down voltage circuit unit raises the step-down voltage to an optimum amount before the step-down voltage drops. Therefore, the auxiliary step-down voltage circuit unit can suppress the drop in the step-down voltage at the time when electric current is consumed by the load. Therefore, it is possible to prevent the differential amplifier from raising the step-down voltage more than necessary.

A semiconductor device receives command signals of plural patterns from the outside. An internal voltage generating circuit generates an internal voltage of an amount corresponding to execution of operations that correspond to the various command signals. The semiconductor device adjusts the internal voltage to an optimum amount before the internal voltage fluctuates. Therefore, the semiconductor device can suppress fluctuation in the internal voltage at the time when electric current is consumed by a load.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a block diagram showing the configuration of a boosting voltage generating circuit disclosed in Japanese Patent Laid-Open No. 9-153284;

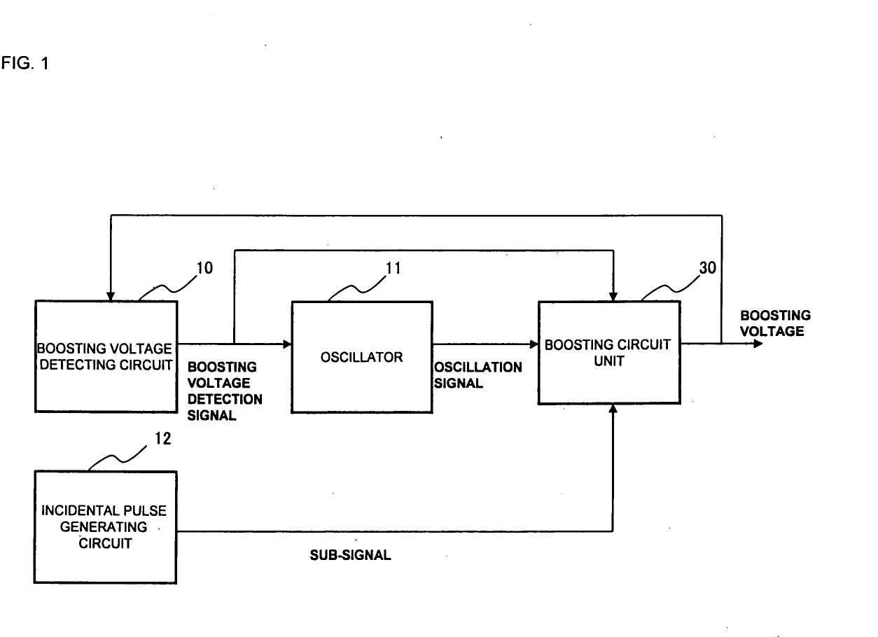

FIG. 2 is a waveform chart showing the operation of the boosting voltage generating circuit shown in FIG. 1;

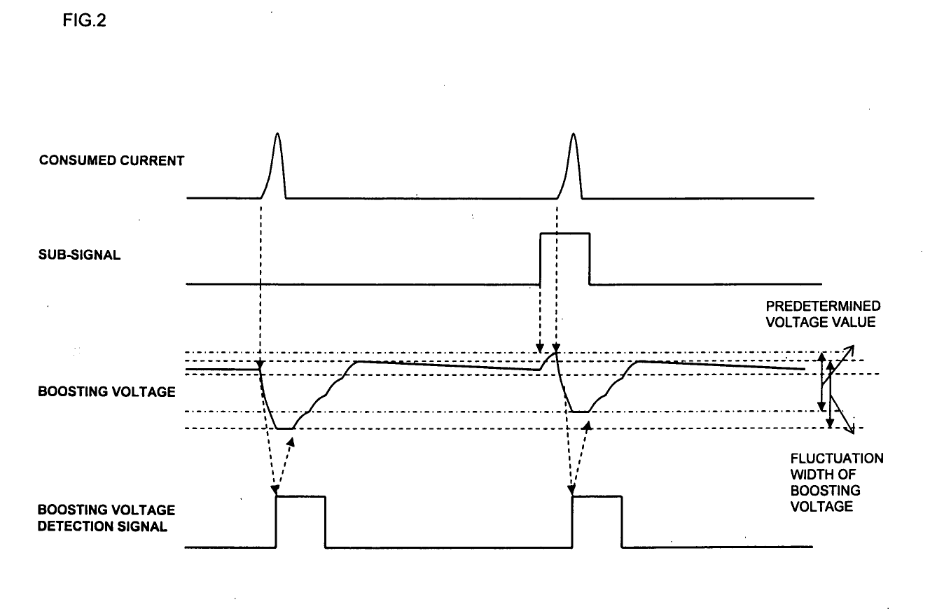

FIG. 3 is a block diagram showing the configuration of a boosting voltage generating circuit according to a first embodiment of the present invention;

FIG. 4 is a circuit diagram showing the configuration of a control circuit shown in FIG. 3;

FIG. 5 is a waveform chart showing the operation of the boosting voltage generating circuit according to the first embodiment;

FIG. 6 is a block diagram showing the configuration of a boosting voltage generating circuit according to a second embodiment of the present invention;

FIG. 7 is a block diagram showing the configuration of a negative voltage generating circuit according to a third embodiment of the present invention;

FIG. 8 is a circuit diagram showing the configuration of a negative voltage detecting circuit shown in FIG. 7;

FIG. 9 is a circuit diagram showing the configuration of a negative voltage circuit unit shown in FIG. 7;

FIG. 10 is a block diagram showing the configuration of a step-down voltage generating circuit according to a fourth embodiment of the present invention;

FIG. 11 is a block diagram showing the configuration of a semiconductor device according to the present invention;

FIG. 12 is a block diagram showing the configuration of a semiconductor memory device according to the present invention;

FIG. 13 is a waveform chart showing a boosting control signal, a first pulse signal, and a second pulse signal at the time when a RAS signal is used as a boosting control signal shown in FIG. 3; and

FIG. 14 is a waveform chart showing a boosting control signal, a first pulse signal, and a third pulse signal at the time when a RAS signal is used as a boosting control signal shown in FIG. 6.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

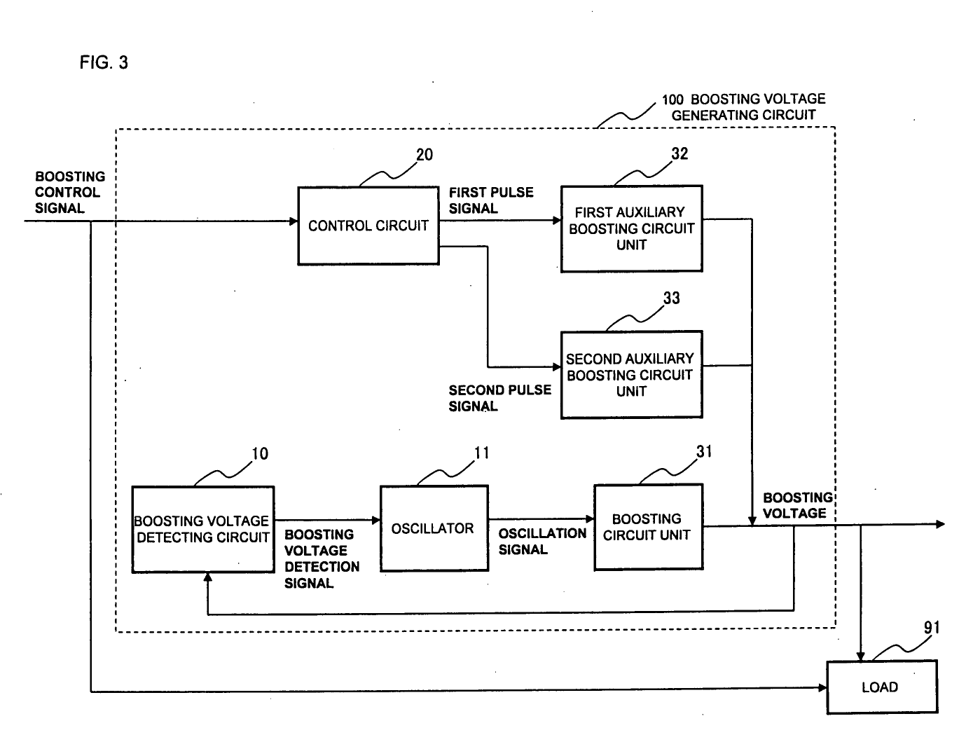

FIG. 3 is a block diagram showing the configuration of a boosting voltage generating circuit according to a first embodiment of the present invention.

As shown in FIG. 3, the boosting voltage generating circuit according to the first embodiment includes boosting voltage detecting circuit 10, oscillator 11, control circuit 20, boosting circuit unit 31, first auxiliary boosting circuit unit 32, and second auxiliary boosting circuit unit 33. Load 91 is connected to a line supplied with a boosting voltage output by the boosting voltage generating circuit.

Boosting voltage detecting circuit 10 measures boosting voltage output by the boosting voltage generating circuit and outputs a boosting voltage detection signal. The configuration of the boosting voltage detecting circuit is described in, for example, Japanese Patent Laid-Open No. 9-153284.

Oscillator 11 outputs an oscillation signal according to the boosting voltage detection signal output from boosting voltage detecting circuit 10. The configuration of the oscillator is described in, for example, Japanese Patent Laid-Open No. 9-153284.

Boosting circuit unit 31 raises the boosting voltage when a pulse signal is input thereto. The configuration of the boosting circuit unit is described in, for example, Japanese Patent Laid-Open No. 9-153284.

First auxiliary boosting circuit unit 32 and second auxiliary boosting circuit unit 33 have the same function as that of boosting circuit unit 31. The amounts of boosting voltage of first auxiliary boosting circuit unit 32 and second auxiliary boosting circuit unit 33, at the time when the pulse signal is input, are different from the amounts of boosting voltage of boosting circuit unit 31 at the time when the pulse signal is input. The amounts of boosting voltage of first auxiliary boosting circuit unit 32 at the time when the pulse signal is input are different from the amounts of boosting voltage of second auxiliary boosting circuit unit 33 at the time when the pulse signal is input.

A boosting control signal is a signal for notifying, immediately before electric current is consumed by load 91 connected to the output of the boosting voltage generating circuit, that electric current will be consumed. Control circuit 20 outputs a pulse signal to first auxiliary boosting circuit unit 32 and second auxiliary boosting circuit unit 33 according to the timing of the consumption of electric current notified by the input boosting control signal.

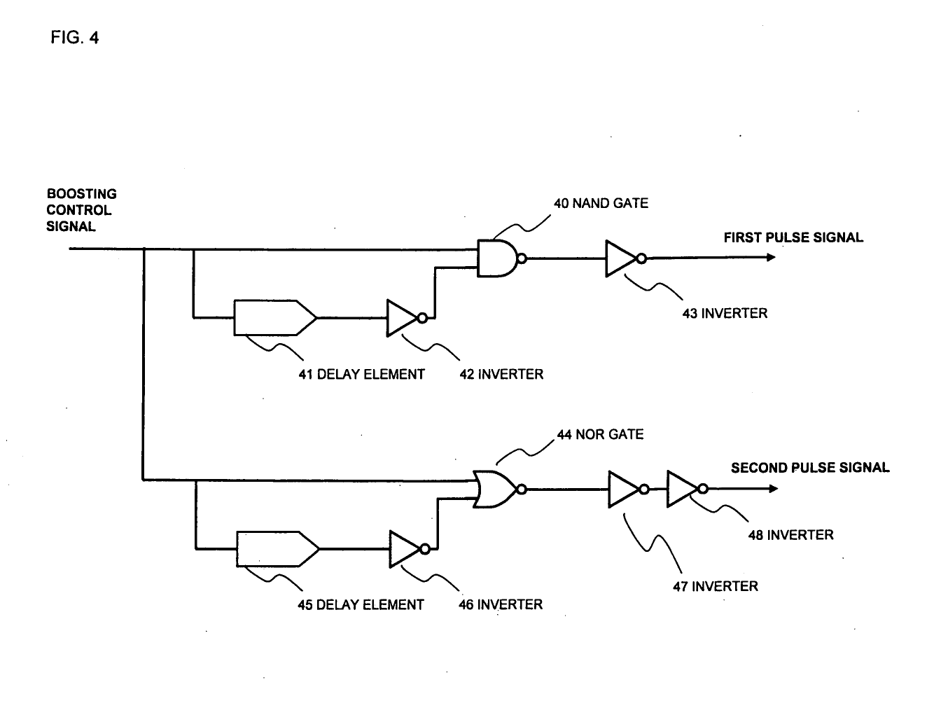

FIG. 4 is a circuit diagram showing a configuration example of control circuit 20.

As shown in FIG. 4, control circuit 20 according to the first embodiment includes NAND gate 40, first delay element 41, first inverter 42, second inverter 43, NOR gate 44, second delay element 45, third inverter 46, fourth inverter 47, and fifth inverter 48.

When an input signal changes from a low level to a high level, control circuit 20 outputs a first pulse signal that changes to the high level only for the delay time according to delay element 41. When the input signal changes from the high level to the low level, control circuit 20 outputs a second pulse signal that changes to the high level only for the delay time according to delay element 45.

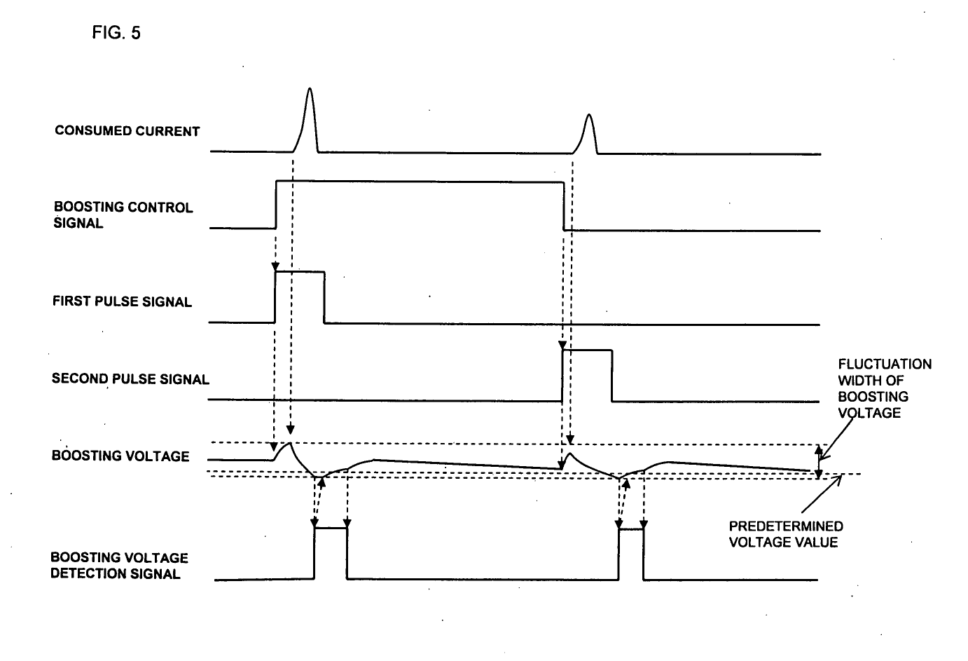

FIG. 5 is a waveform chart showing the operation of the boosting voltage generating circuit according to the first embodiment.

When the boosting control signal changes from the low level to the high level, control circuit 20 outputs a pulse signal, that changes to the high level only for the delay time according to delay element 41, to first auxiliary boosting circuit unit 32. When the pulse signal is input, first auxiliary boosting circuit unit 32 raises the voltage supplied to load 91.

Thereafter, when electric current is consumed by load 91 connected to the output of the boosting voltage generating circuit, the boosting voltage drops. When boosting voltage detecting circuit 10 detects that the boosting voltage has dropped, boosting voltage detecting circuit 10 sets a boosting voltage detection signal to the high level and actuates oscillator 11. When an oscillation signal is input, boosting circuit unit 31 raises the boosting voltage. When boosting voltage detecting circuit 10 detects that the boosting voltage has risen higher than a predetermined voltage value, boosting voltage detecting circuit 10 sets the boosting voltage detection signal to the low level and stops oscillator 11. When oscillation of the input signal stops, boosting circuit unit 31 stops the voltage boosting operation and stops the rise of the boosting voltage.

Similarly, when the boosting control signal changes from the high level to the low level, control circuit 20 outputs a pulse signal, that changes to the high level only for the delay time according to delay element 45, to second auxiliary boosting circuit unit 33. When the pulse signal is input, second auxiliary boosting circuit unit 33 raises the voltage supplied to load 91. Since operation after that is the same as that performed when the boosting control signal changes from the low level to the high level, explanation of this operation is omitted.

Load 91 is activated in response to the boosting control signal and operating on the boosting voltage to perform a circuit function.

In the boosting voltage generating circuit according to the first embodiment, the amounts of boosting voltage can be separately set for first auxiliary boosting circuit unit 32 and second auxiliary boosting circuit unit 33. Therefore, the optimum amount of boosting voltage for making up the drop in the boosting voltage at the time when the boosting control signal changes from the low level to the high level can be set for first auxiliary boosting circuit unit 32. The optimum amount of boosting voltage for making up the drop in the boosting voltage at the time when the boosting control signal changes from the high level to the low level can be set for second auxiliary boosting circuit unit 33. The boosting voltage is raised to the optimum amount by first auxiliary boosting circuit unit 32 and second auxiliary boosting circuit unit 33 before the boosting voltage drops. Therefore, the boosting voltage generating circuit according to the first embodiment can suppress the drop in the boosting voltage at the time when electric current is consumed by the load.

Boosting circuit unit 31 boosts the boosting voltage to reset the boosting voltage only when a slight drop in the boosting voltage, at the time when electric current is consumed by the load, or when voltage drop due to very small current consumption not notified by the boosting control signal is detected. Therefore, since boosting circuit unit 31 can design a small amount of boosting voltage, the boosting voltage can be prevented from rising more than necessary. As a result, it is possible to suppress fluctuation in the boosting voltage output from the boosting voltage generating circuit.

In the configuration example explained above, first auxiliary boosting circuit unit 32 and second auxiliary boosting circuit unit 33 are used in the boosting voltage generating circuit according to the first embodiment. However, the number of auxiliary boosting circuit units is not limited. The number of auxiliary boosting circuit units may be one or may be three or more.

The boosting control signal may be any signal and control circuit 20 may have any configuration as long as a pulse wave can be output from control circuit 20 before the boosting voltage drops.

### Second Embodiment

A second embodiment of the present invention is explained below.

Characteristics of the respective circuits need to be changed in first auxiliary boosting circuit unit 32 and second auxiliary boosting circuit unit 33 according to the first embodiment because the amounts of boosting voltage thereof at the time when the pulse signal is input are different. In the second embodiment, the boosting voltage of respective auxiliary boosting circuit units at the time when a pulse signal is input is set the same. Therefore, since characteristics of the respective auxiliary boosting circuit units can be set the same, the same components can be used.

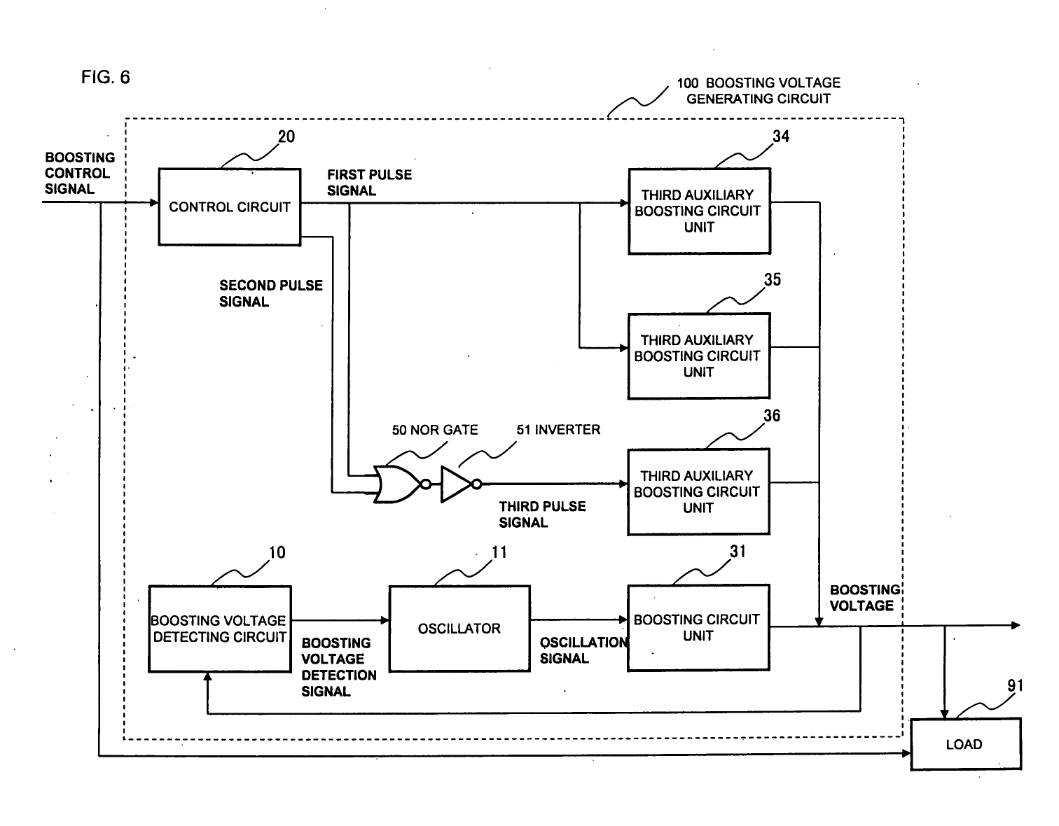

FIG. 6 is a block diagram showing the configuration of a boosting voltage generating circuit according to the second embodiment.

As shown in FIG. 6, the boosting voltage generating circuit according to the second embodiment includes boosting voltage detecting circuit 10, oscillator 11, control circuit 20, NOR gate 50, inverter 51, boosting circuit unit 31, and third auxiliary boosting circuit units 34, 35, and 36. Load 91 is connected to a line supplied with a boosting voltage output by the boosting voltage generating circuit.

The configurations of boosting voltage detecting circuit 10, oscillator 11, control circuit 20, and boosting circuit unit 31 are the same as those in the first embodiment.

Third auxiliary boosting circuit units 34, 35, and 36 have the same function as that of boosting circuit unit 31. The amounts of boosting voltage of third auxiliary boosting circuit units 34, 35, and 36, at the time when a pulse signal is input, are different from the amounts of boosting voltage of boosting circuit unit 31 at the time when a pulse signal is input. However, the amounts of boosting voltage of third auxiliary boosting circuit units 34, 35, and 36, at the time when a pulse signal is input, are the same. Therefore, third auxiliary boosting circuit units 34, 35, and 36 are configured by the same circuit.

NOR gate 50 and inverter 51 are arranged in the boosting voltage generating circuit such that a third pulse signal input to third auxiliary boosting circuit unit 36 is an OR of a first pulse signal and a second pulse signal output from a control circuit.

When a boosting control signal changes from a low level to a high level, control circuit 20 outputs a pulse signal, that changes to the high level only for the delay time according to delay element 41, to third auxiliary boosting circuit units 34, 35, and 36. When the pulse signal input, third auxiliary boosting circuit units 34, 35, and 36 raise the voltage supplied to load 91.

Similarly, when the boosting control signal changes from the high level to the low level, control circuit 20 outputs a pulse signal, that changes to the high level only for the delay time according to delay element 45, to third auxiliary boosting circuit unit 36. When the pulse signal is input, third auxiliary boosting circuit unit 36 raises the voltage supplied to load 91.

In other words, in the boosting voltage generating circuit according to the second embodiment, the amount of boosting voltage, at the time when the boosting control signal changes from the low level to the high level, is three times as large as the amount of boosting voltage at the time when the boosting control signal changes from the high level to the low level. By changing the number of auxiliary boosting circuit units to which the first pulse signal is input and the number of auxiliary boosting circuit units to which the third pulse signal is input, it is possible to change the amount of boosting voltage at the time when the boosting control signal changes.

According to this embodiment, since characteristics of the respective auxiliary boosting circuit units can be set to be the same, in addition to the same advantages as those of the boosting voltage generating circuit according to the first embodiment, it is possible to reduce cost through the common use of components.

### Third Embodiment

In the first and second embodiments, the boosting voltage generating circuit that generates boosting voltage that is higher than the power supply voltage supplied from the outside is explained. A third embodiment of the present invention is an example in which the present invention is applied to a negative voltage generating circuit that generates negative voltage that is lower than the ground.

The negative voltage generating circuit according to the present invention is a negative voltage generating circuit that generates negative voltage that is lower than the ground. The negative voltage generating circuit includes a negative voltage detecting circuit that detects whether the negative voltage is lower than a predetermined voltage value and outputs the result of the detection, an oscillator that performs an oscillating operation according to the detection result of the negative voltage detecting circuit, a negative voltage circuit unit that generates the negative voltage using an oscillation signal from the oscillator, a control circuit that outputs, when a negative voltage control signal for notifying that electric current is consumed by a load supplied with the negative voltage is input, a pulse signal at the timing of the notification, and a first auxiliary negative voltage circuit unit that supplies, using the pulse signal from the control circuit, voltage that is lower than the negative voltage that corresponds to the current amount consumed by the load, to the load.

The control circuit outputs, when the negative voltage control signal is input, plural pulse signals corresponding to the timing when electric current is consumed by the load. The negative voltage generating circuit further includes a second auxiliary negative voltage circuit unit that supplies, using the pulse signals output from the control circuit, voltage that is different from the voltage supplied by the first auxiliary voltage circuit unit that corresponds to the current amount consumed by the load, to the load.

The control circuit outputs, when the negative voltage control signal is input, plural pulse signals corresponding to the timing when electric current is consumed by the load. The first auxiliary negative voltage circuit unit includes third auxiliary negative voltage circuit units that supply, using the pulse signals output from the control circuit, a voltage lower than the negative voltage corresponding to the current amount consumed by the load, to the load.

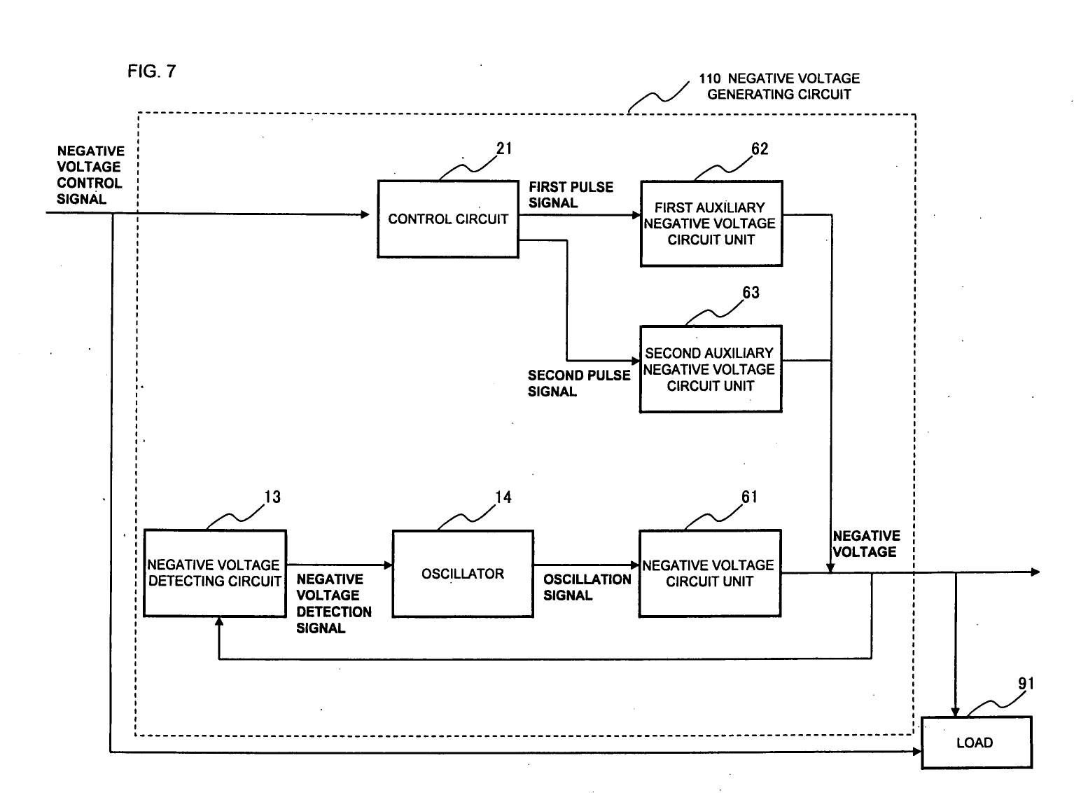

FIG. 7 is a block diagram showing the configuration of the negative voltage generating circuit according to the third embodiment.

As shown in FIG. 7, the negative voltage generating circuit according to the third embodiment includes negative voltage detecting circuit 13, oscillator 14, control circuit 21, negative voltage circuit unit 61, first auxiliary negative voltage circuit unit 62, and second auxiliary negative voltage circuit unit 63. Load 91 is connected to a line supplied with a negative voltage output by the negative voltage generating circuit.

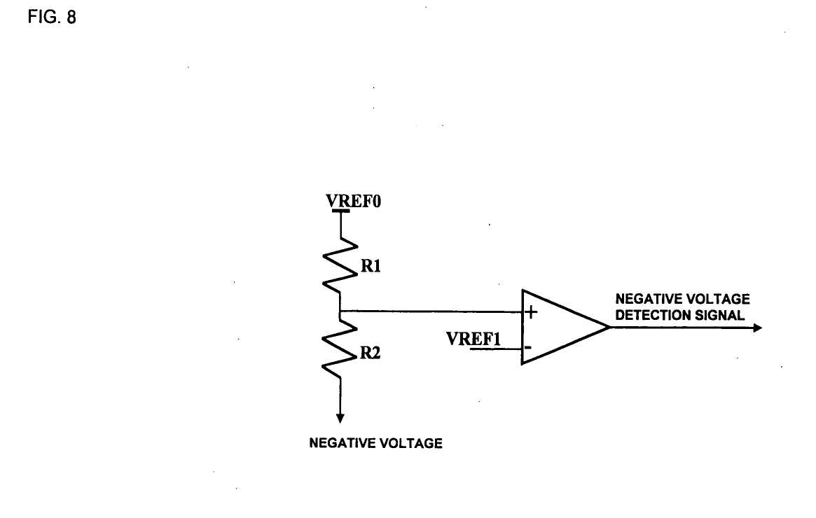

Negative voltage detecting circuit 13 measures negative voltage output by the negative voltage generating circuit and outputs a negative voltage detection signal. The configuration of negative voltage detecting circuit 13 is shown in FIG. 8. Negative voltage detecting circuit 13 includes two resistors R1 and R2 inserted in series between reference voltage VREF0 and the negative voltage and a differential circuit that compares the voltage of a connection node for resistors R1 and R2 and reference voltage VREF1. When the negative voltage is higher than a predetermined voltage value, i.e., when the negative voltage is closer to 0 than the predetermined voltage value, negative voltage detecting circuit 13 sets a negative voltage detection signal to a high level. When the negative voltage is lower than the predetermined voltage value, negative voltage detecting circuit 13 sets the negative voltage detection signal to a low level. Resistors R1 and R2 are circuits for dividing reference voltage VREF0 and the negative voltage. Therefore, these circuits are not limited to the configuration shown in FIG. 8 and may be configured by three or more resistors.

Oscillator 14 outputs an oscillation signal according to the negative voltage detection signal output from negative voltage detecting circuit 13. The configuration of the oscillator is described in, for example, Japanese Patent Laid-Open No. 9-153284.

The configuration of control circuit 21 is the same as that of control circuit 20 of the boosting voltage generating circuit according to the first embodiment.

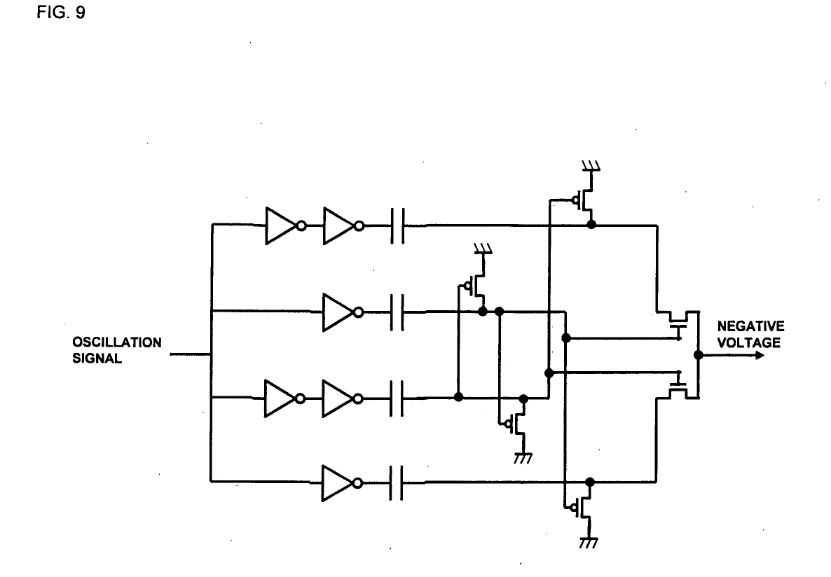

When the pulse signal is input, negative voltage circuit unit 61 lowers the negative voltage, i.e., increases the absolute value of the negative voltage in a minus direction (hereinafter referred to as “lower” in the third embodiment). The configuration of the negative voltage circuit unit 61 is shown in FIG. 9. Negative voltage circuit unit 61 includes plural inverters, plural step-down capacitors, and plural switch elements for adding up output voltages of the respective step-down capacitors at a predetermined timing. An oscillation signal from oscillator 14 is input to the negative voltage circuit unit 61. When the oscillation signal output from oscillator 14 is input, negative voltage circuit unit 61 lowers the output voltage. When the input of the oscillation signal is stopped, negative voltage circuit unit 61 stops the lowering of the output voltage.

First auxiliary negative voltage circuit 62 and second auxiliary negative voltage circuit unit 63 have the same function as that of negative voltage circuit unit 61. The amounts of voltage drop of first auxiliary negative voltage circuit unit 62 and second auxiliary negative voltage circuit unit 63, at the time when a pulse signal is input, are different from the amounts of voltage drop of negative voltage circuit unit 61 at the time when a pulse signal is input. The amount of voltage drop of first auxiliary negative voltage circuit unit 62, at the time when a pulse signal is input, is different from the amount of voltage drop of second auxiliary negative voltage circuit unit 63 at the time when a pulse signal is input.

The negative voltage control signal is a signal for notifying, immediately before electric current is consumed by load 91 connected to an output of the negative voltage generating circuit, that the current will be consumed by load 91. Control circuit 21 outputs a pulse signal to first auxiliary negative voltage circuit unit 62 and second auxiliary negative voltage circuit unit 63 according to the timing when electric current is consumed notified by the input negative voltage control signal.

When the negative voltage control signal changes from the low level to the high level, control circuit 21 outputs a pulse signal that changes to the high level only for the delay time according to delay element 41 to first auxiliary negative voltage circuit unit 62. When the pulse signal is input, first auxiliary negative voltage circuit unit 62 lowers the voltage supplied to load 91.

Thereafter, when electric current is consumed by load 91 connected to the output of the negative voltage generating circuit, the negative voltage rises, i.e., approaches 0 (hereinafter referred to as “rise” in the third embodiment). When negative voltage detecting circuit 13 detects that the negative voltage has risen, negative voltage detecting circuit 13 sets the negative voltage detection signal to the high level and actuates oscillator 14. When an oscillation signal is input, negative voltage circuit unit 61 lowers the negative voltage. When negative voltage detecting circuit 13 detects that the negative voltage has dropped lower than the predetermined voltage value, negative voltage detecting circuit 13 sets the negative voltage detection signal to the low level and stops oscillator 14. When the oscillation of the input signal stops, negative voltage circuit unit 61 stops the output of the negative voltage and stops the drop in the negative voltage.

Similarly, when the negative voltage control signal changes from the high level to the low level, control circuit 21 outputs a pulse signal that changes to the high level only for the delay time according to delay element 45 to second auxiliary negative voltage circuit unit 63. When the pulse signal is input, second auxiliary negative voltage circuit unit 63 lowers voltage supplied to load 91. Since operation after that is the same as the operation at the time when the negative voltage control signal changes from the low level to the high level, explanation of the operation is omitted.

Load 91 is activated in response to the negative voltage control signal and operating on the negative voltage to perform a circuit function.

If the negative voltage generating circuit explained above is used, as in the boosting voltage generating circuit according to the first embodiment, since the amount of voltage drop of negative voltage circuit unit 61 can be designed small, it is possible to prevent the negative voltage from dropping more than necessary. As a result, it is possible to suppress fluctuation in the negative voltage output from the negative voltage generating circuit.

In the boosting voltage generating circuit shown in FIG. 6, characteristics of plural auxiliary negative voltage circuit units can be set to be the same by replacing the boosting voltage detecting circuit with the negative voltage detecting circuit, replacing the boosting circuit unit with the negative voltage circuit unit, and replacing the third auxiliary boosting circuit units with the third auxiliary negative voltage circuit units. The third auxiliary negative voltage circuit units have the same function as that of negative voltage circuit unit 61. The amount of voltage drop of the third auxiliary negative voltage circuit units, at the time when pulse signal is input, is different from the amount of voltage drop of the negative voltage circuit unit 61 at the time when pulse signal is input. However, the amounts of voltage drop of the third auxiliary negative voltage circuit units at the time when pulse signal are input are the same. Since characteristics of the respective auxiliary negative voltage circuit units can be set to be the according to this configuration, it is possible to reduce cost through the common use of components.

### Fourth Embodiment

In the first and second embodiments, the boosting voltage generating circuit that generates boosting voltage higher than power supply voltage supplied from the outside is explained. A fourth embodiment according to the present invention is an example in which the present invention is applied to a step-down voltage generating circuit that generates step-down voltage that is lower than power supply voltage supplied from the outside.

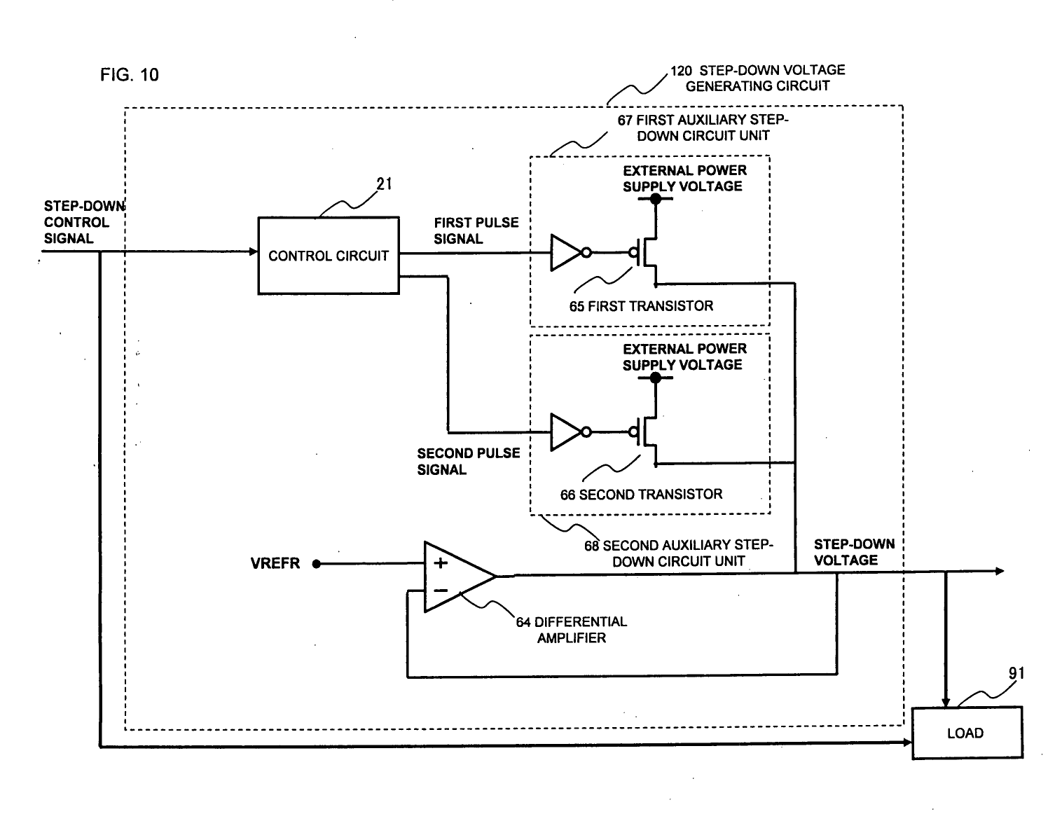

FIG. 10 is a block diagram showing the configuration of the step-down voltage generating circuit according to the fourth embodiment.

As shown in FIG. 10, the step-down voltage generating circuit according to the fourth embodiment includes differential amplifier 64, control circuit 21, first auxiliary step-down circuit unit 67, and second auxiliary step-down circuit unit 68. Load 91 is connected to a line supplied with a step-down voltage output by the step-down voltage generating circuit.

Step-down voltage output by the step-down voltage generating circuit and reference voltage VREFR are input to differential amplifier 64. When the step-down voltage is negatively fed back, differential amplifier 64 operates such that the step-down voltage is equal to reference voltage VREFR.

The configuration of control circuit 21 is the same as that of control circuit 20 of the boosting voltage generating circuit according to the first embodiment.

First auxiliary step-down circuit unit 67 includes an inverter and first transistor 65 for supplying external power supply voltage at a predetermined timing. Second auxiliary step-down circuit unit 68 includes an inverter and second transistor 66 for supplying external power supply voltage at a predetermined timing. First transistor 65 and second transistor 66 have different sizes.

The step-down control signal is a signal for notifying, immediately before electric current is consumed by load 91 connected to an output of the step-down voltage generating circuit, that electric current will be consumed. When the step-down control signal changes from a low level to a high level, control circuit 21 outputs a pulse signal that changes to the high level only for the delay time according to delay element 41 to first transistor 65. When the pulse signal is input, first auxiliary step-down circuit unit 67 raises the voltage that is supplied to load 91.

Similarly, when the step-down control signal changes from the high level to the low level, control circuit 21 outputs a pulse signal that changes to the high level only for the delay time according to delay element 45 to a second transistor 66. When the pulse signal is input, second auxiliary step-down circuit unit 67 raises the voltage that is supplied to load 91.

Load 91 is activated in response to the step-down control signal and operating on the step-down voltage to perform a circuit function.

In the step-down voltage generating circuit according to the fourth embodiment, by setting first transistor 65 and second transistor 66 to optimum sizes, respectively, it is possible to set the step-down voltage to an optimum rise amount for making up the drop in the step-down voltage at the time when the step-down control signal changes.

Consequently, it is possible to prevent differential amplifier 64 from raising the step-down voltage more than necessary when electric current is consumed by the load and it is possible to suppress fluctuation in the step-down voltage output from the step-down voltage generating circuit.

### Fifth Embodiment

A fifth embodiment of the present invention is an example in which the boosting voltage generating circuit according to the first or second embodiment, the negative voltage generating circuit according to the third embodiment, or the step-down voltage generating circuit according to the fourth embodiment is provided in a semiconductor device.

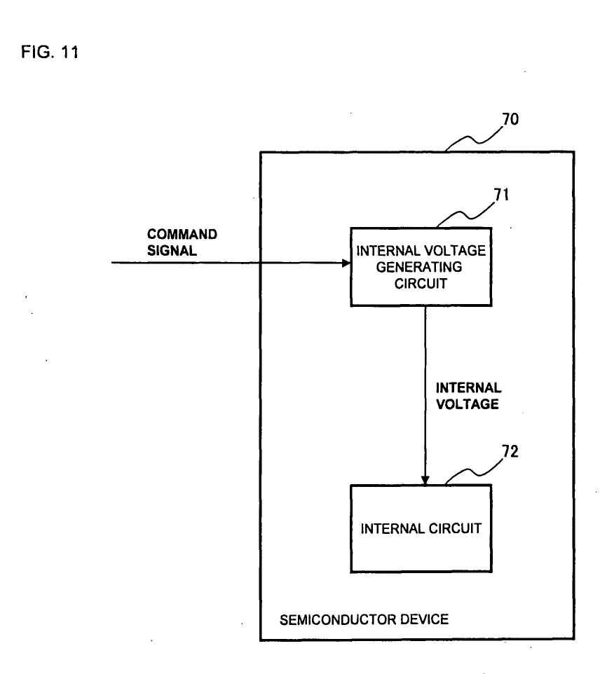

FIG. 11 is a block diagram showing the configuration of the semiconductor device including the boosting voltage generating circuit according to the first or second embodiment, the negative voltage generating circuit according to the third embodiment, or the step-down voltage generating circuit according to the fourth embodiment.

As shown in FIG. 11, semiconductor device 70 includes internal voltage generating circuit 71 and internal circuit 72.

As internal voltage generating circuit 71, the boosting voltage generating circuit according to the first or second embodiment, the negative voltage generating circuit according to the third embodiment, or the step-down voltage generating circuit according to the fourth embodiment is used.

Internal circuit 72 provides a predetermined function of the semiconductor device.

A command signal for specifying the operation of the semiconductor device is input to internal voltage generating circuit 71 as a boosting control signal, a negative voltage control signal, or a step-down control signal. Internal voltage generating circuit 71 raises or lowers internal voltage supplied to internal circuit 72 according to the command signal from the outside.

Internal voltage generating circuit 71 can raise or lower voltage supplied to internal circuit 72 to an optimum amount prior to current consumption in internal circuit 72. Therefore, it is possible to suppress fluctuation in voltage at the time when electric current is consumed by internal circuit 72.

### Sixth Embodiment

A sixth embodiment is an example in which the boosting voltage generating circuit according to the first or second embodiment, the negative voltage generating circuit according to the third embodiment, or the step-down voltage generating circuit according to the fourth embodiment is provided in a semiconductor memory device.

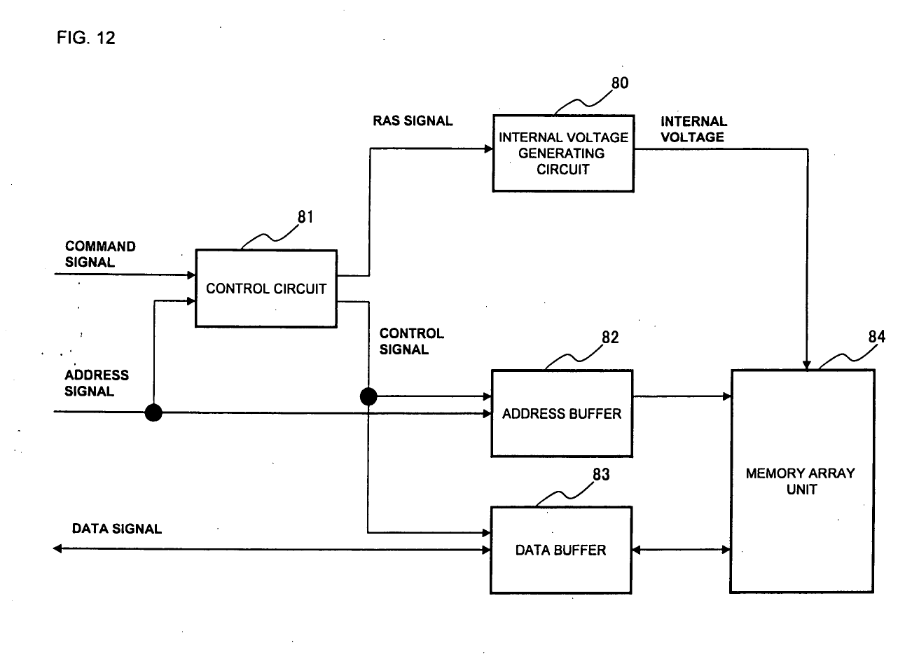

FIG. 12 is a block diagram showing the configuration of the semiconductor memory device including the boosting voltage generating circuit according to the first or second embodiment, the negative voltage generating circuit according to the third embodiment, or the step-down voltage generating circuit according to the fourth embodiment.

As shown in FIG. 12, the semiconductor memory device includes internal voltage generating circuit 80, control circuit 81, address buffer 82 that temporarily stores an address signal input from the outside, data buffer 83 that temporarily stores a data signal input from the outside and a data signal output to the outside, and memory array 84 that stores data.

Control circuit 81 outputs a control signal for causing the semiconductor memory device to perform a predetermined operation according to a command signal such as a RAS signal or a CAS signal input from the outside. Control circuit 81 outputs the input RAS signal to internal voltage generating circuit 80. Control circuit 81 is configured by using a well-know logic circuit.

As internal voltage generating circuit 80, the boosting voltage generating circuit according to the first or second embodiment, the negative voltage generating circuit according to the third embodiment, or the step-down voltage generating circuit according to the fourth embodiment is used. Internal voltage generating circuit 80 uses the input RAS signal as a boosting control signal, a negative voltage control signal, or a step-down control signal.

In the semiconductor memory device, when a memory is accessed, a RAS (Row Address Strobe) signal is used in order to designate a row address of a memory cell to be accessed. In the semiconductor memory device, an active command (hereinafter referred to as ACT command) is output before readout and writing of data and a pre-charge command (hereinafter referred to as PRE command) is output after the readout and writing of the data. When the ACT command and the PRE command are output, the semiconductor memory device consumes a large amount of electric current. The RAS signal changes to a high level when the ACT command is input and changes to a low level when the PRE command is input. According to this characteristic, the RAS signal is used as the boosting control signal, the negative voltage control signal, or the step-down control signal.

First, an example in which the boosting voltage generating circuit according to the first embodiment is provided in the semiconductor memory device is explained below.

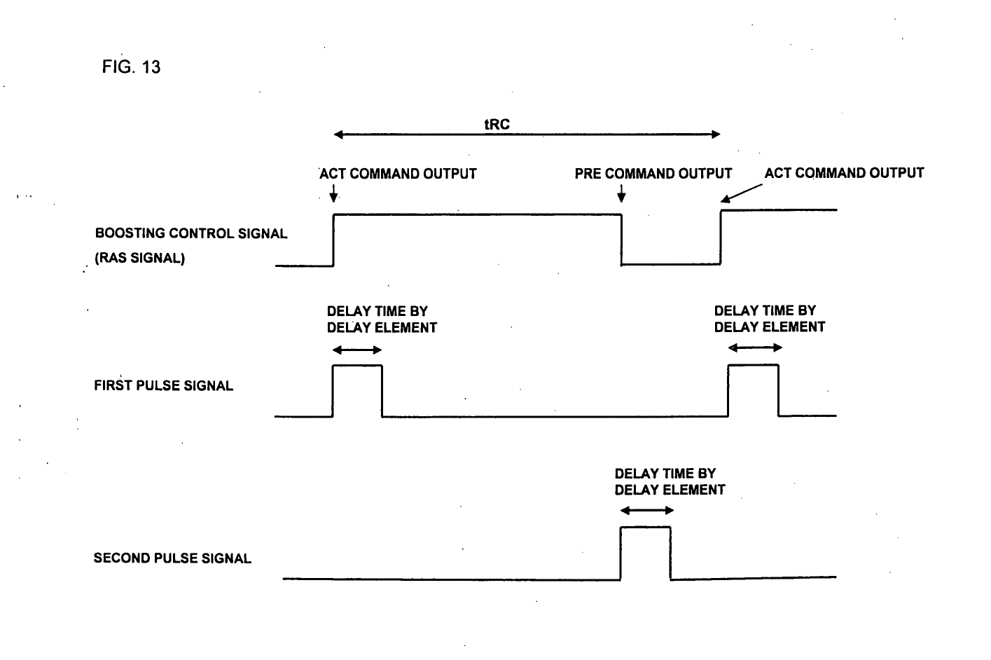

FIG. 13 is a waveform chart showing the boosting control signal, a first pulse signal, and a second pulse signal when the RAS signal is used as the voltage control signal. The time delayed according to delay element 41 and delay element 45 is set to a time shorter than a half of cycle time tRC of the RAS signal such that pulses of the first pulse signal and the second pulse signal do not overlap each other.

The operation of the boosting voltage generating circuit when the RAS signal is used as the boosting control signal input to the boosting voltage generating circuit is explained with reference to FIG. 13. When readout or writing of data is performed by the semiconductor memory device, the RAS signal changes. When the RAS signal as an input signal changes, control circuit 20 outputs a pulse signal. When the pulse signal is input, first auxiliary boosting circuit unit 32 or second auxiliary boosting circuit unit 33 raises voltage supplied to a load.

Boosting voltage is raised to an optimum amount by first auxiliary boosting circuit unit 32 and second auxiliary boosting circuit unit 33 before the boosting voltage drops. Therefore, in the boosting voltage generating circuit according to the present invention, it is possible to suppress the drop in the boosting voltage at the time when electric current is consumed by the load.

Boosting circuit unit 31 boosts the dropped boosting voltage in order to reset the boosting voltage to a predetermined voltage value only when a slight drop in the boosting voltage, at the time when electric current is consumed by the load, or when voltage drop due to very small current consumption except during readout or writing of data is detected. Therefore, since the amounts of boosting voltage of boosting circuit unit 31 can be designed small, it is possible to prevent the boosting voltage from rising more than necessary.

An example in which the boosting voltage generating circuit according to the second embodiment is provided in the semiconductor memory device is explained below.

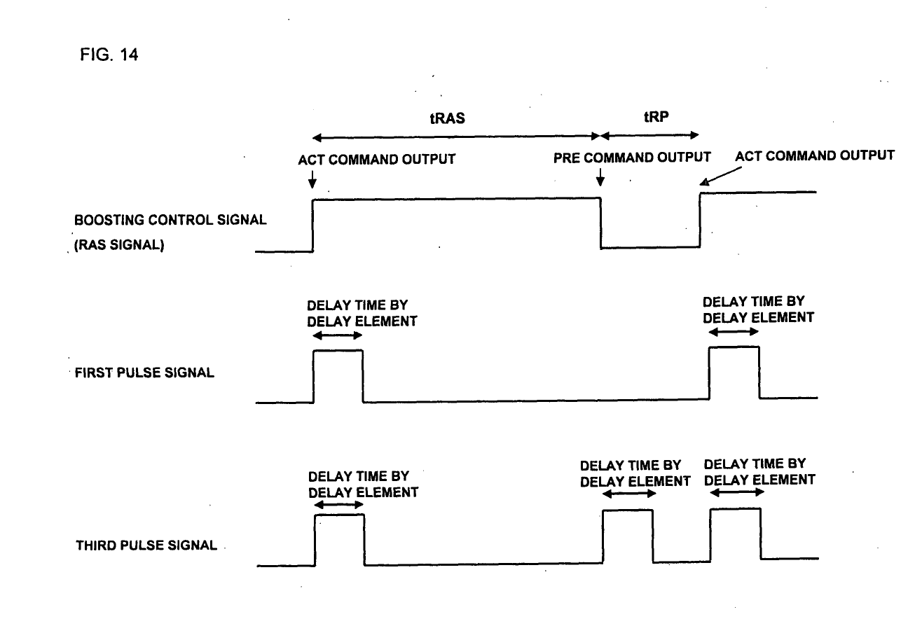

FIG. 14 is a waveform chart showing the boosting control signal, a first pulse signal, and a third pulse signal when the RAS signal is used as the boosting control signal. The time delayed according to delay element 41 and delay element 45 is set to a time shorter than a half of access time tRAS of the RAS signal and a time shorter than a half of pre-charge time tRP of the RAS signal such that pulses of the first pulse signal and the third pulse signal do not overlap each other.

By changing the number of auxiliary boosting circuit units that input the first pulse signal and the number of auxiliary boosting circuit units that input the third pulse signal, it is possible to change the amount of boosting voltage with respect to the drop in boosting voltage at the time when the ACT command is output and the drop in boosting voltage at the time when the PRE command is output.

Not only the boosting voltage generating circuits according to the first and second embodiments but also negative voltage generating circuits according to the third embodiments and the step-down voltage generating circuits according to the fourth embodiments can be provided in the semiconductor memory device.

In the sixth embodiment, the example in which the RAS signal is used as the boosting control signal, the negative voltage control signal, or the step-down control signal is explained. The boosting control signal, the negative voltage control signal, or the step-down control signal may be any signal as long as a pulse wave is output before internal voltage changes. For example, when the step-down voltage generating circuit is provided in the semiconductor device, a CAS signal for designating a column address of a memory cell can also be used as the step-down control signal.

It is apparent that the present invention is not limited to the above embodiments, but may be modified and changed without departing from the scope and spirit of the invention.

What is claimed is:

1. A semiconductor device that generates boosting voltage higher than power supply voltage supplied from outside, the boosting voltage generating circuit comprising:
a boosting voltage detecting circuit that detects whether the boosting voltage is lower than a predetermined voltage value and outputs a result of the detection;
an oscillator that performs an oscillating operation according to the detection result of the boosting voltage detecting circuit;
a boosting circuit unit that generates the boosting voltage using an oscillation signal from the oscillator;
a control circuit that outputs, when a boosting control signal for notifying that electric current is consumed by a load supplied with the boosting voltage is input, a pulse signal at the timing of the notification; and
a first auxiliary boosting circuit unit that supplies, using the pulse signal output from the control circuit, voltage higher than the boosting voltage corresponding to a current amount consumed by the load, to the load.

2. The semiconductor device according to claim 1, wherein
the control circuit outputs, when the boosting control signal is input, plural pulse signals corresponding to a timing when electric current is consumed by the load, and
the boosting voltage generating circuit further includes a second auxiliary boosting circuit unit that supplies, using the pulse signals output from the control circuit, voltage different from the voltage supplied by the first auxiliary boosting circuit unit corresponding to the current amount consumed by the load, to the load.

3. The semiconductor device according to claim 1, wherein
the control circuit outputs, when the boosting voltage control signal is input, plural pulse signals corresponding to a timing when electric current is consumed by the load, and
the first auxiliary boosting circuit unit includes plural third auxiliary boosting circuit units that supply, using the pulse signals output from the control circuit, a voltage higher than the boosting voltage corresponding to the current amount consumed by the load, to the load.

4. A semiconductor device that generates step-down voltage lower than power supply voltage supplied from outside, the step-down voltage generating circuit comprising:
a differential amplifier that brings the step-down voltage close to a predetermined voltage value;
a control circuit that outputs, when a step-down control signal for notifying that electric current is consumed by a load supplied with the step-down voltage is input, a pulse signal at the timing of the notification; and
a first transistor that switches, using the pulse signal output from the control circuit, a supply of voltage corresponding to a current amount consumed by the load, to the load.

5. The semiconductor device according to claim 4, wherein
the control circuit outputs, when the step-down control signal is input, plural pulse signals corresponding to a timing when electric current is consumed by the load, and
the step-down voltage generating circuit further includes a second transistor that switches, using the pulse signals output from the control circuit, a supply of voltage different from the voltage supplied by the switching of the first transistor corresponding to the current amount consumed by the load, to the load.

6. A semiconductor device that receives command signals of plural patterns from outside and executes operations corresponding to the respective command signals, the semiconductor device comprising an internal voltage generating circuit that generates internal voltage for executing the operations corresponding to the command signals, wherein
the internal voltage generating circuit generates, on the basis of at least a first command signal among the command signals of the plural patterns, voltage of an amount corresponding to execution of operation that corresponds to the first command signal.

7. The semiconductor device according to claim 6, wherein the internal voltage generating circuit generates, on the basis of a second command signal among the command signals of the plural patterns different from the first command, voltage of an amount corresponding to execution of operation corresponding to the second command signal different from the voltage of the amount corresponding to the execution of the operation that corresponds to the first command.

8. The semiconductor device according to claim 6, further comprising a memory array that stores data, wherein
the first command signal is a pulse signal output at a timing when a RAS signal for designating a row address of a memory cell to be accessed changes from a low level to a high level.

9. The semiconductor device according to claim 7, further comprising a memory array that stores data, wherein
the first command signal is a pulse signal output at a timing when a RAS signal for designating a row address of a memory cell to be accessed changes from a low level to a high level, and
the second command signal is a pulse signal output at a timing when the RAS signal for designating a row address of a memory cell to be accessed changes from the high level to the low level.

10. A semiconductor device comprising:
a line supplied with a boosting voltage;
a load circuit connected to the line, the load circuit being activated in response to a control signal and operating on the boosting voltage to perform a circuit function; and
an energizing circuit responding to the control signal to enlarge a voltage level on the line.

11. The semiconductor device according to claim 10, wherein
the control signal includes a leading edge and a trailing edge,
the energizing circuit includes a control circuit which receives the control signal to output a first signal corresponding to one of the leading and trailing edges and a first circuit which enlarges the voltage level on the line in response to the first signal.

12. The semiconductor device according to claim 11, wherein
the control circuit which receives the control signal to further output a second signal corresponding to the other of the leading and trailing edges,
the energizing circuit further includes a second circuit which enlarges the voltage level on the line in response to the second signal.

13. The semiconductor device according to claim 12, wherein
the first and second circuits are different in enlargement capability from each other.

14. The semiconductor device according to claim 10, further comprising
a boosting voltage detecting circuit that detects whether the voltage level on the line is lower than a predetermined voltage value and outputs a result of the detection,
an oscillator that performs an oscillating operation according to the detection result of the boosting voltage detecting circuit, and
a boosting circuit unit that generates the boosting voltage using an oscillation signal from the oscillator.
